(19) United States
(12) Patent Application Publication
(10) Pub. No.: US 2024/0321676 A1
(43) Pub. Date: Sep. 26, 2024

(54) METHOD OF MANUFACTURING POWER SEMICONDUCTOR MODULE, AND POWER SEMICONDUCTOR MODULE MANUFACTURED THEREBY

(71) Applicant: AMOSENSE CO., LTD., Cheonan-si, Chungcheongnam-do (KR)

(72) Inventor: Jihyung LEE, Cheonan-si (KR)

(73) Assignee: AMOSENSE CO., LTD., Cheonan-si, Chungcheongnam-do (KR)

(21) Appl. No.: 18/269,940

(22) PCT Filed: Dec. 23, 2021
(86) PCT No.: PCT/KR2021/019682

§ 371 Date: Jun. 27, 2023

(30) Foreign Application Priority Data
Dec. 28, 2020 (KR) 10-2020-0184611

(51) Int. Cl. H01L 23/373; H01L 23/15

(52) U.S. Cl. CPC H01L 23/3736; H01L 23/15

(57) ABSTRACT

The present invention relates to a method of manufacturing a power semiconductor module and a power semiconductor module manufactured thereby, the method comprising the steps of: removing thermal stress by annealing a base plate; disposing a brazing filler layer on the upper surface of the base plate; and laminating and brazing a ceramic substrate onto the base plate having the brazing filler layer disposed thereon.

### TECHNICAL FIELD

The present disclosure relates to a method of manufacturing a power semiconductor module and a power semiconductor module manufactured thereby, and more particularly, to a method of manufacturing a power semiconductor module having a bonding structure of a base plate and a ceramic substrate and a power semiconductor module manufactured thereby.

### BACKGROUND ART

Generally, in a power semiconductor module, a base plate is formed in a rectangular plate shape, and is formed of an aluminum or copper material. Such a base plate may be bonded to a lower surface of a ceramic substrate, and may be used as a heat sink. The base plate may be bonded by soldering onto the lower surface of the ceramic substrate so as to be good for heat dissipation.

However, since the base plate in the related art has a thermal expansion coefficient of 17 ppm/K, flexure may occur due to a difference in thermal expansion in a bonding process with the ceramic substrate. Further, solder paste may melt at a high temperature to cause the flexure or defect of the base plate.

As solution schemes for this, the ceramic substrate and the base plate are bonded at a temperature equal to or lower than 250° C. with AlSiC or similar materials. According to the bonding structure of the base plate and the ceramic substrate in the related art, the base plate is bonded by soldering to the ceramic substrate through the medium of a solder preform. In this case, as the solder preform, SAC305 made of a composition containing Sn, Ag, and Cu, and the soldering temperature is 230 to 350° C.

However, the bonding structure of the base plate and the ceramic substrate in the related art may cause an increase of a process cost due to the solder paste and solder preform used for the bonding and the process, such as vacuum bonding equipment, and may cause bonding reliability and yield problems.

### SUMMARY OF INVENTION

### Technical Problem

An object of the present disclosure is to provide a method of manufacturing a power semiconductor module and a power semiconductor module manufactured thereby, which can improve bonding reliability of a base plate and a ceramic substrate, can achieve high-reliability bonding for various base plates, and can achieve process simplification and saving of process costs.

### Solution to Problem

In order to achieve the above object, a method of manufacturing a power semiconductor module according to an embodiment of the present disclosure may include: removing a thermal stress by annealing a base plate; disposing a brazing filler layer on an upper surface of the base plate; and laminating and brazing a ceramic substrate onto the base plate on which the brazing filler layer is disposed.

In the removing of the thermal stress by the annealing, an annealing temperature may be 600° C. to 750° C.

In the disposing of the brazing filler layer, the brazing filler layer having a thickness that is equal to or larger than 5 μm and equal to or smaller than 100 μm may be disposed on the upper surface of the base plate by any one method of paste application, foil attachment, and P-filler.

The brazing may be performed at 800° C. to 950° C., and upper weighting or pressurizing is performed during brazing.

Meanwhile, a power semiconductor module manufactured by a method of manufacturing a power semiconductor module according to an embodiment of the present disclosure may include: a base plate from which a thermal stress is removed by being annealed; a brazing filler layer disposed on an upper surface of the base plate; and a ceramic substrate that is brazed onto the upper surface of the base plate through the brazing filler layer.

Here, the base plate may be annealed at a temperature of 600° C. to 750° C.

In the ceramic substrate, an electrode pattern composed of a metal may be formed on a ceramic base material.

The brazing filler layer may be made of a material including at least one of Ag, Cu, AgCu, and AgCuTi.

The base plate may be composed of at least one of Cu, Al, W, AlSiC, CuMo, CuW, Cu/CuMo/Cu, Cu/Mo/Cu, and Cu/W/Cu, or a composite material thereof.

Meanwhile, the base plate may include: a first metal sheet; a second metal sheet formed on an upper surface of the first metal sheet; and a third metal sheet formed on an upper surface of the second metal sheet, wherein the first metal sheet and the third metal sheet are formed of the same metal material, and wherein the second metal sheet is formed of a metal material different from the metal material of the first metal sheet and the third metal sheet.

Here, the second metal sheet may be composed of one metal sheet of Mo, W, CuMo, and CuW, or a mixed metal sheet thereof, and the first metal sheet and the third metal sheet may be composed a Cu metal sheet.

Further, the power semiconductor module may include a brazing filler disposed between the first metal sheet and the second metal sheet and between the second metal sheet and the third metal sheet, and the first metal sheet, the second metal sheet, and the third metal sheet may be brazed onto each other through the brazing filler.

Here, the brazing filler may be made of a material including at least one of Ag, Cu, AgCu, and AgCuTi.

### Advantageous Effects of Invention

The present disclosure has the effects of heightening the bonding strength through the brazing of the base plate onto the ceramic substrate, making the process simplification possible since the vacuum bonding equipment, such as usage of the solder preform, is not required, and heightening the bonding reliability since the processing defect is prevented and the bonding strength is further heightened through carrying out of the upper weighting or pressurizing.

Further, the present disclosure has the effects of improving the bonding reliability and heightening the thermal conductivity more than three times the thermal conductivity of the existing soldering bonding since the brazing is performed by melting the brazing filler layer after the removal of the thermal stress of the base plate beforehand.

Further, the present disclosure has the effects of maximizing the heat dissipation effect since the brazing filler layer facilitates the heat movement and thus fast moving the heat of the ceramic substrate to the base plate.

### BRIEF DESCRIPTION OF DRAWINGS

FIG. 1 is an exploded perspective view illustrating a bonding structure of a base plate and a ceramic substrate for a power semiconductor module according to an embodiment of the present disclosure.

FIG. 2 is a cross-sectional view illustrating a bonding structure of a base plate and a ceramic substrate for a power semiconductor module according to an embodiment of the present disclosure.

FIG. 3 is a flowchart illustrating a method of manufacturing a power semiconductor module according to an embodiment of the present disclosure.

FIG. 4 is a cross-sectional view illustrating a bonding structure of a base plate and a ceramic substrate for a power semiconductor module according to another embodiment of the present disclosure.

FIG. 5 is a cross-sectional view illustrating a bonding structure of a base plate and a ceramic substrate for a power semiconductor module according to still another embodiment of the present disclosure.

### DESCRIPTION OF EMBODIMENTS

Hereinafter, embodiments of the present disclosure will be described in detail with reference to the accompanying drawings.

The present disclosure is featured on a bonding structure of a base plate and a ceramic substrate among constitutions included in a power semiconductor module, and explanation will be made around this.

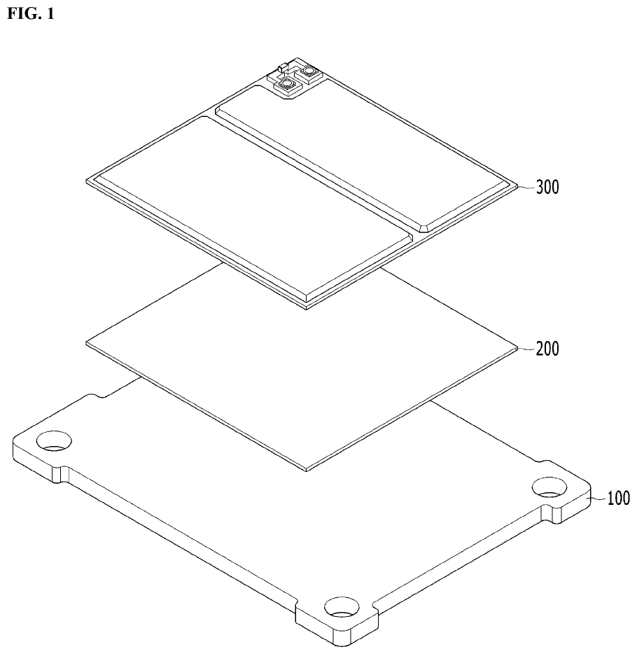

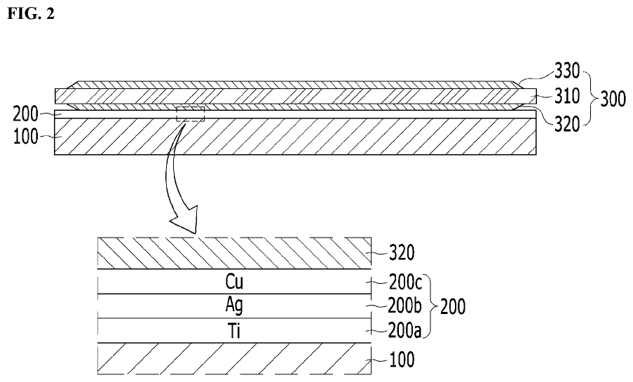

FIG. 1 is an exploded perspective view illustrating a bonding structure of a base plate and a ceramic substrate for a power semiconductor module according to an embodiment of the present disclosure, and FIG. 2 is a cross-sectional view illustrating a bonding structure of a base plate and a ceramic substrate for a power semiconductor module according to an embodiment of the present disclosure.

As illustrated in FIGS. 1 and 2, a power semiconductor module according to an embodiment of the present disclosure may include a base plate 100 from which a thermal stress is removed by being annealed, a brazing filler layer 200 disposed on an upper surface of the base plate 100, and a ceramic substrate 300 that is brazed onto the upper surface of the base plate 100 through the brazing filler layer 200.

In the power semiconductor module, a semiconductor chip (not illustrated) may be mounted on an upper surface of the ceramic substrate 300. The semiconductor chip may be a semiconductor chip, such as Si, VCSEL, SiC, and GaN.

The ceramic substrate 300 may be any one of an active metal brazing (AMB) substrate, a direct bonded copper (DBC) substrate, and a thick printing copper (TPC) substrate. Here, in order to heighten the heat dissipation efficiency of heat being generated from the semiconductor chip, the ceramic substrate 300 may be provided as a ceramic substrate composed of a ceramic base material 310 and metal layers 320 and 330 formed on at least one surface of the ceramic base material 310.

As an example, the ceramic base material 310 may be any one of AlN, SiN, and Si₃N₄. The metal layers 320 and 330 may be formed as an electrode pattern for mounting the semiconductor chip and an electrode pattern for mounting a driving element through brazing of a metal foil onto the ceramic base material 310. For example, the metal layers 320 and 330 may be formed as electrode patterns in an area where the semiconductor chip or peripheral parts are to be mounted. As an example, the metal foil is an aluminum foil or a copper foil. As an example, the metal foil is brazed onto the ceramic base material 310 through firing at 780° C. to 1100° C. Such a substrate is called an active metal brazing (AMB) substrate. In an embodiment, although the AMB substrate is exemplified, a direct bonding copper (DBC) substrate, a thick printing copper (TPC) substrate, or a direct brazed aluminum (DBA) substrate may also be applied. Here, the AMB substrate is most suitable for durability and heat dissipation efficiency.

As an example, the ceramic base material 310 is any one of alumina (Al₂O₃), AlN, SiN, and Si₃N₄, and the metal layers 320 and 330 are composed of one of Cu, Cu alloy, OFC, EPT Cu, and Al. The OFC is an oxygen-free copper.

The base plate 100 may be bonded to a lower surface of the ceramic substrate 300 to be used as a heat sink for dissipating heat generated from the semiconductor chip, and may be brazed onto the ceramic substrate 300 in a state where thermal stress has been removed therefrom through being annealed at a temperature of 600° C. to 750° C.

The base plate 100 may be formed in a rectangular plate shape having a predetermined thickness. The base plate 100 is formed of a material that can heighten the heat dissipation efficiency. As an example, the base plate 100 may be composed of at least one of Cu, Al, W, AlSiC, CuMo, CuW, Cu/CuMo/Cu, Cu/Mo/Cu, and Cu/W/Cu, or a composite material thereof. The materials of Cu, Al, W, AlSiC, CuMo, CuW, Cu/CuMo/Cu, Cu/Mo/Cu, and Cu/W/Cu have prominent thermal conductivity, and the materials of AlSiC, CuMo, CuW, Cu/CuMo/Cu, Cu/Mo/Cu, and Cu/W/Cu have a low thermal expansion coefficient, and thus can minimize the flexure occurrence when being bonded to the ceramic substrate 300.

The brazing filler layer 200 may be disposed on an upper surface of the base plate 100. The brazing filler layer 200 is to secure the bonding characteristic between the base plate 100 and the ceramic substrate 300.

The brazing filler layer 200 has a thickness equal to or larger than 5 μm and equal to or smaller than 100 μm. The brazing filler layer 200 may be formed as a thin film of a multilayer structure. The thin film of the multilayer structure is to heighten the bonding force through complementation of the poor performance. The brazing filler layer 200 may be composed of a material including at least one of Ag, Cu, AgCu, and AgCuTi. The Ag and Cu have a high thermal conductivity, and thus heighten the heat dissipation efficiency by facilitating heat transfer between the ceramic substrate 300 and the base plate 100 simultaneously with the role of heightening the bonding force. The Ti has a good wettability, and thus facilitates attachment of Ag and Cu onto the base plate 100.

As an example, the brazing filler layer 200 may be composed of a two-layer structure including an Ag layer and a Cu layer formed on the Ag layer. Further, the brazing filler layer 200 may be composed of a three-layer structure including a Ti layer 200a, an Ag layer 200b formed on the Ti layer 200a, and a Cu layer 200c formed on the Ag layer 200b. The brazing filler layer 200 may be used for bonding of the base plate 100 and the ceramic substrate 300, and after the brazing, the boundary of the multilayer structure may become ambiguous.

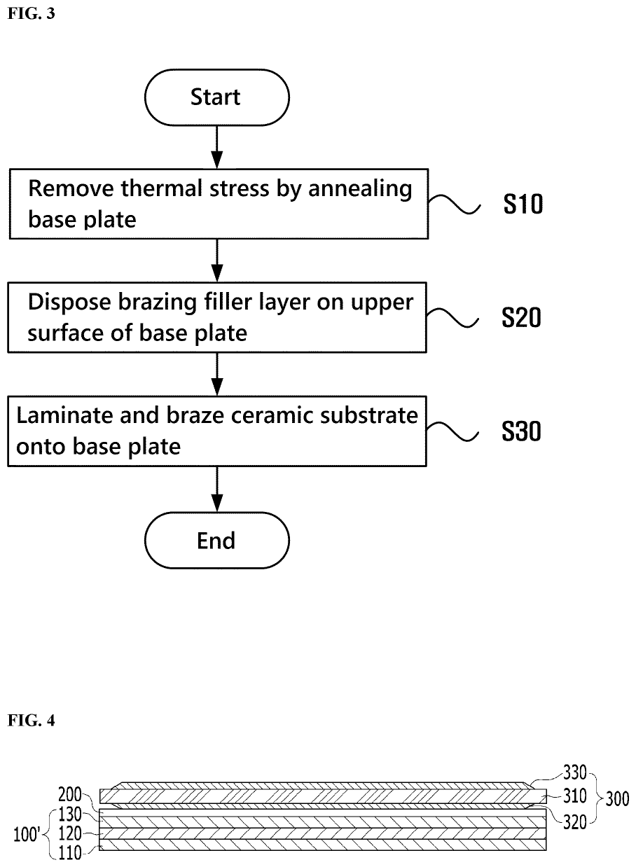

FIG. 3 is a flowchart illustrating a method of manufacturing a power semiconductor module according to an embodiment of the present disclosure.

As illustrated in FIG. 4, a method of manufacturing a power semiconductor module according to an embodiment of the present disclosure may include: removing a thermal stress by annealing a base plate 100 (S10); disposing a brazing filler layer 200 on an upper surface of the base plate 100 (S20); and laminating and brazing a ceramic substrate 300 onto the base plate 100 on which the brazing filler layer 200 is disposed (S30).

In the step (S10) of removing the thermal stress by annealing the base plate 100, a plate, which is composed of at least one of Cu, Al, W, AlSiC, CuMo, CuW, Cu/CuMo/Cu, Cu/Mo/Cu, and Cu/W/Cu, or a composite material thereof, is prepared as the base plate 100. Preferably, a plate, which is composed of at least one of AlSiC, CuMo, CuW, Cu/CuMo/Cu, Cu/Mo/Cu, and Cu/W/Cu, or a composite material thereof, is prepared as the base plate 100. The materials of AlSiC, CuMo, CuW, Cu/CuMo/Cu, Cu/Mo/Cu, and Cu/W/Cu have a low thermal expansion coefficient as compared to Cu and Al, and thus can minimize a flexure phenomenon occurring due to a difference in thermal expansion coefficients at a high temperature.

The thickness of the base plate 100 may be in the range of 1.0 mm to 3.0 mm. Preferably, the thickness of the base plate 100 becomes equal to or larger than 2.0 mm, and thus is good for heat dissipation to minimize the flexure occurrence.

The step (S10) of removing the thermal stress by annealing the base plate 100 is to remove the thermal stress of the base plate 100 beforehand.

In the process in which the base plate 100 and the ceramic substrate 300 are brazed at a high temperature of 800° C. to 950° C., the thermal stress may occur due to the difference in thermal expansion coefficients. By such thermal stress, the bonded region of the base plate 100 and the ceramic substrate 300 may be damaged, and the heat dissipation characteristic may be degraded since the heat transfer is not properly performed.

Accordingly, by passing through the step (S10) of removing the thermal stress by annealing the base plate 100 before a step (S30) of brazing by completely melting the brazing filler layer 200 disposed between the base plate 100 and the ceramic substrate 300, the thermal stress given to the base plate 100 is removed beforehand, and through this, the thermal stress that is generated by thermal expansion and thermal contraction in the brazing process of the base plate 100 and the ceramic substrate 300 is relieved to improve the bonding reliability. Further, since the bonding region is not damaged, the heat transfer effect becomes prominent to improve the heat dissipation characteristic. In case of the existing bonding structure using the soldering, the thermal conductivity has appeared 110 W/m·K, and the thermal conductivity of the brazing structure of the base plate 100 and the ceramic substrate 300 according to an embodiment of the present disclosure has appeared 370 W/m·K. That is, the thermal conductivity characteristic of the brazing structure according to the present disclosure has appeared to be about more than three times the thermal conductivity characteristic of the existing soldering structure.

The step (S10) of removing the thermal stress by the annealing may be performed at a temperature of 600° C. to 750° C. in an electric furnace or a gas furnace. If the annealing temperature is unable to reach 600° C., the thermal stress removal may take more time than necessary, whereas if the annealing temperature exceeds 750° C., the effect by the annealing is saturated to be not economical. Accordingly, it is preferable that the annealing temperature is 600° C. to 750° C.

Further, after the step (S10) of removing the thermal stress by the annealing, the dimensional accuracy may be heightened or the flexure may be controlled by additionally performing a sizing process depending on the material of the base plate 100.

In the step (S20) of disposing the brazing filler layer 200 on the upper surface of the base plate 100, the brazing filler layer 200 having the thickness equal to or larger than 5 μm and equal to or smaller than 100 μm is disposed on the upper surface of the base plate 100 in any one method of paste application, foil attachment, and P-filler. The brazing filler layer 200 may be made of a material including at least one of Ag, Cu, AgCu, and AgCuTi.

In the step (S30) of laminating and brazing the ceramic substrate 300 on the base plate 100 on which the brazing filler layer 200 is disposed, the ceramic substrate 300 may be provided as a ceramic substrate 300 composed of a ceramic base material 310 and metal layers 320 and 330 brazed on at least one surface of the ceramic base material 310. As an example, the ceramic substrate may be provided as any one of an AMB substrate, a DBC substrate, a TPC substrate, and a DBA substrate.

The brazing step (S30) may be performed at a temperature equal to or higher than 450° C., and preferably, at a temperature of 800° C. to 950° C., and upper weighting or pressurizing may be performed to heighten the bonding force during the brazing.

As an example, in the brazing step (S30), a laminate, in which the ceramic substrate 300 is laminated on the base plate 100 having an upper surface on which the brazing filler layer 200 is disposed, may be prepared and disposed between an upper pressing jig and a lower pressing jig in a brazing furnace (not illustrated) so that the upper and lower surfaces of the laminate can be pressed during heating thereof.

Further, the laminate may be disposed in the brazing furnace, and the upper part of the laminate may be pressed with a weight body disposed on the upper surface of the laminate. The performing of the upper weighting or pressurizing in the brazing step is for void-free bonding.

The heating temperature of the brazing furnace may be controlled to be at 800° C. or more, and preferably, in the range of 800° C. to 950° C., for an efficient brazing process. As an example, a desirable brazing temperature is 870° C.

Since the brazing does not require the vacuum bonding equipment, such as usage of the solder preform, the process simplification is possible, and the bonding reliability is heightened since the processing defect is prevented and the bonding strength is heightened through carrying out of the upper weighting or pressurizing.

Through the brazing step (S30), the base plate 100 may be integrally formed with the ceramic substrate 300.

Here, although the present disclosure exemplarily illustrates that the base plate 100 is bonded to the metal layer 320 of the ceramic substrate 300, the bonding is not limited thereto, and the base plate 100 may be bonded even to an area where the metal layer 320 is not formed on the ceramic substrate 300 through the brazing filler layer 200.

In the above-described embodiment, the base plate 100 is composed of a single-layer structure. However, the base plate may also be composed of a multilayer structure to have a low thermal expansion coefficient (low CTE).

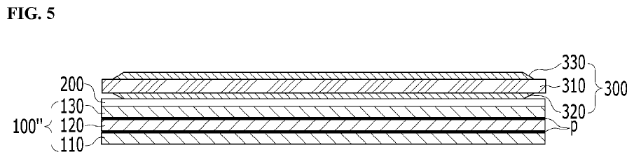

FIG. 4 is a cross-sectional view illustrating a bonding structure of a base plate and a ceramic substrate for a power semiconductor module according to another embodiment of the present disclosure, and FIG. 5 is a cross-sectional view illustrating a bonding structure of a base plate and a ceramic substrate for a power semiconductor module according to still another embodiment of the present disclosure. Another embodiment and still another embodiment are different from the above-described embodiment on the point that the base plate is composed of a multilayer structure.

As illustrated in FIG. 4, the base plate 100′ may be formed to have a three or more layer structure, and may have a thickness equal to or larger than 1.0 mm. As an example, the base plate 100′ may be formed to have a multilayer structure in which metal sheets of heterogeneous materials are laminated with the thickness equal to or larger than 1.0 mm, and thus may be good for heat dissipation with the flexure occurrence minimized.

The base plate 100′ may include a first metal sheet 110, a second metal sheet 120, and a third metal sheet 130. That is, the base plate 100′ may have a three-layer structure in which the second metal sheet 120 is formed on an upper surface of the first metal sheet 110, and the third metal sheet 130 is formed on an upper surface of the second metal sheet 120.

The first metal sheet 110 and the third metal sheet 130 may be formed of the same metal material, and the second metal sheet 120 may be formed of a metal material that is different from the metal material of the first metal sheet 110 and the third metal sheet 130. It is preferable that the second metal sheet 120 is formed of a metal material having a low thermal expansion coefficient, and the first metal sheet and the third metal sheet 130 are formed of a material having an excellent thermal conductivity. It is possible to manufacture the base plate 100′ having the low thermal expansion coefficient by bonding the first metal sheet 110 and the third metal sheet 130 formed of the metal material having the excellent thermal conductivity onto the upper surface and the lower surface of the second metal material 120 formed of the metal material having the low thermal expansion coefficient.

As an example, the first metal sheet 110 and the third metal sheet 130 may be composed of a metal sheet of Cu, and the second metal sheet 120 may be composed of one of metal sheets of Mo, W, CuMo, and CuW or a mixed metal sheet thereof.

Here, in case of a CPC material in which the first metal sheet 110 of the base plate 100′ is composed of the metal sheet of Cu, the second metal sheet 120 is composed of the metal sheet of CuMo, and the third metal sheet 130 is composed of the metal sheet of Cu, the CuMo is to prevent the flexure occurrence through the low thermal expansion coefficient, and Cu is to secure the thermal conductivity for the heat dissipation.

That is, the base plate 100′ may be provided as the 3-layer metal sheet structure in which the metal sheet of Cu having a relatively high thermal expansion coefficient and high thermal conductivity is formed on the upper surface and the lower surface of the metal sheet of CuMo having a relatively low thermal expansion coefficient. According to the base plate 100′ as described above, the flexure of the metal sheet of Cu can be absorbed by the metal sheet of CuMo, and thus the flexure phenomenon occurring due to the difference in thermal expansion coefficients at the high temperature can be reduced.

The base plate 100′ may be formed to have the 3-layer structure of Cu/CuMo/Cu by coating the Cu layer on the upper surface and the lower surface of the metal sheet of CuMo through infiltration of the metal sheet of CuMo into molten metal, and then rolling the Cu-coated metal sheet.

Further, as illustrated in FIG. 5, the base plate 100″ may have a three-layer structure in which the second metal sheet 120 is bonded onto the upper surface of the first metal sheet 110, and the third metal sheet 130 is bonded onto the upper surface of the second metal sheet 120. By forming the multilayer structure through bonding of the first metal sheet 110, the second metal sheet 120, and the third metal sheet 130 onto each other, the base plate 100″ with a desired thickness can be manufactured with no threshold for thickness.

The base plate 100″ may have a three-layer laminated structure in which the second metal sheet 120 is brazed onto the upper surface of the first metal sheet 110 through a brazing filler p, and the third metal sheet 130 is brazed onto the upper surface of the second metal sheet 120 through the brazing filler p.

The brazing filler p may be made of a material including at least one of Ag, Cu, AgCu, and AgCuTi. As an example, the brazing filler p may be composed of a 2-layer structure including an Ag layer and a Cu layer formed on the Ag layer. Further, the brazing filler p may be composed of a 3-layer structure including a Ti layer, an Ag layer formed on the Ti layer, and a Cu layer formed on the Ag layer.

Further, as an example, by forming a 3-layer structure or a multilayer bonding structure through bonding of the metal sheet of Cu on the upper surface and the lower surface of the metal sheet of CuMo through the brazing filler p, the base plate 100″ having a thickness of 2.0 mm or more can be manufactured.

In case that the base plate 100″ is formed as a 3-layer bonding metal sheet structure of Cu/CuMo/Cu or AlSiC, it has the prominent bonding characteristic in bonding onto the ceramic substrate 300, and may have the thermal expansion coefficient of 6.8 to 12 ppm/K and the thermal conductivity of 220 to 370 W/m·K.

According to the present disclosure as described above, since the base plate is brazed onto the ceramic substrate at the high temperature, the bonding reliability can be heightened, the process simplification becomes possible, and the process cost can be saved.

In particular, since the brazing does not require the vacuum bonding equipment like the usage of the existing solder preform, the process simplification becomes possible, and by performing the upper weighting or pressurizing, the processing defect is prevented, the bonding strength is heightened, and thus the bonding reliability is heightened.

Further, since the thermal stress is removed before the base plate is brazed onto the ceramic substrate, the bonding reliability can be improved, and the heat dissipation condition required in the power semiconductor module can be satisfied with the prominent thermal conductivity.

Although it has been exemplified that the above-described bonding structure of the base plate and the ceramic substrate is applied to the power semiconductor module, it is also possible to apply the same to various bonding structures requiring high reliability bonding.

Further, although the present disclosure has been described through separation into an embodiment, another embodiment, and still another embodiment, the embodiments are mixedly applicable.

Preferred embodiments of the present disclosure have been disclosed in the drawings and the description. Here, although specific terms have been used, this is merely for the purpose of explaining the present disclosure, but is not for limiting the meanings or limiting the scope of the present disclosure described in claims. Accordingly, it will be understood by those of ordinary skill in the art to which the present disclosure pertains that various modifications or other equivalent embodiments are possible therefrom. Accordingly, the authentic technical scope of the present disclosure should be determined by the technical ideas of the appended claims.

1. A method of manufacturing a power semiconductor module, the method comprising:
removing a thermal stress by annealing a base plate;
disposing a brazing filler layer on an upper surface of the base plate; and
laminating and brazing a ceramic substrate onto the base plate on which the brazing filler layer is disposed.

2. The method of claim 1, wherein in the removing of the thermal stress by the annealing, an annealing temperature is 600° C. to 750° C.

3. The method of claim 1, wherein in the disposing of the brazing filler layer, the brazing filler layer having a thickness that is equal to or larger than 5 μm and equal to or smaller than 100 μm is disposed on the upper surface of the base plate by any one method of paste application, foil attachment, and P-filler.

4. The method of claim 1, wherein the brazing is performed at 800° C. to 950° C., and upper weighting or pressurizing is performed during brazing.

5. A power semiconductor module comprising:
a base plate from which a thermal stress is removed by being annealed;
a brazing filler layer disposed on an upper surface of the base plate; and
a ceramic substrate that is brazed onto the upper surface of the base plate through the brazing filler layer.

6. The power semiconductor module of claim 5, wherein the base plate is annealed at a temperature of 600° C. to 750° C.

7. The power semiconductor module of claim 5, wherein in the ceramic substrate, an electrode pattern composed of a metal is formed on a ceramic base material.

8. The power semiconductor module of claim 5, wherein the brazing filler layer is made of a material including at least one of Ag, Cu, AgCu, and AgCuTi.

9. The power semiconductor module of claim 5, wherein the base plate is composed of at least one of Cu, Al, W, AlSiC, CuMo, CuW, Cu/CuMo/Cu, Cu/Mo/Cu, and Cu/W/Cu, or a composite material thereof.

10. The power semiconductor module of claim 5, wherein the base plate comprises:
a first metal sheet;
a second metal sheet formed on an upper surface of the first metal sheet; and
a third metal sheet formed on an upper surface of the second metal sheet,
wherein the first metal sheet and the third metal sheet are formed of the same metal material, and
wherein the second metal sheet is formed of a metal material different from the metal material of the first metal sheet and the third metal sheet.

11. The power semiconductor module of claim 10, wherein the second metal sheet is composed of one metal sheet of Mo, W, CuMo, and CuW, or a mixed metal sheet thereof, and
wherein the first metal sheet and the third metal sheet are composed a Cu metal sheet.

12. The power semiconductor module of claim 10, comprising a brazing filler disposed between the first metal sheet and the second metal sheet and between the second metal sheet and the third metal sheet,
wherein the first metal sheet, the second metal sheet, and the third metal sheet are brazed onto each other through the brazing filler.

13. The power semiconductor module of claim 12, wherein the brazing filler is made of a material including at least one of Ag, Cu, AgCu, and AgCuTi.
